(19) United States
(12) Patent Application Publication
(10) Pub. No.: US 2011/0235414 A1
(43) Pub. Date: Sep. 29, 2011

(54) SEMICONDUCTOR MEMORY DEVICE

(76) Inventors: Takafumi Ikeda, Yokohama-shi (JP); Hiroki Murotani, Chigasaki-shi (JP)

(21) Appl. No.: 13/052,375

(22) Filed: Mar. 21, 2011

(30) Foreign Application Priority Data
Mar. 23, 2010 (JP) 2010-066942

(51) Int. Cl. G11C 16/10; G11C 16/06; G11C 16/04

(52) U.S. Cl. 365/185.03; 365/185.22; 365/185.18

(57) ABSTRACT

According to one embodiment, a semiconductor memory device comprises a memory cell array, a controller. A memory cell array comprises bit lines, and memory cells configured to store different states, i.e., m values or n values. When storing the n values in a memory cell, the controller performs a first method of applying a bit-line voltage to a first bit line connected to the memory cell, and setting a second bit line adjacent to the first bit line at 0 V, in a read operation and in a verify operation. When storing the m values in the memory cell, the controller performs a second method of applying the bit-line voltage to all the bit lines in a read operation, and setting the first bit line and the second bit line at the bit-line voltage or 0 V in a verify operation, in accordance with whether the write is complete.

### CROSS-REFERENCE TO RELATED APPLICATIONS

This application is based upon and claims the benefit of priority from Japanese Patent Application No. 2010-066942, filed Mar. 23, 2010; the entire contents of which are incorporated herein by reference.

### FIELD

Embodiments described herein relate generally to a semiconductor memory device.

### BACKGROUND

A nonvolatile semiconductor memory device that is a NAND flash memory using an EEPROM and capable of storing multilevel data has been proposed. In the NAND flash memory, all or half of memory cells arranged in the row direction (word-line direction) are simultaneously selected from a memory cells arranged in a matrix. Data write or read is performed for the selected cells at once.

The shrinking of the nonvolatile semiconductor memory device of this kind has significantly advanced. Accordingly, the spaces between cells adjacent to each other in the bit-line direction and word-line direction are very small. As the space between adjacent cells decreases, the capacitance (FG-FG capacitance) between the floating gates of the adjacent cells increases. This poses a threshold voltage Vth of a cell in which data is written earlier fluctuates in accordance with data to be written in an adjacent cell later due to the FG-FG capacitance. Especially in a multilevel memory that stores a plurality of data (n bits) in one cell, a plurality of threshold voltages must be set. Therefore, the threshold voltage distribution per data is controlled to a very small distribution. As a consequence, the threshold voltage fluctuates in accordance with data in an adjacent cell is larger.

To solve the above-mentioned problem, Jpn. Pat. Appln. KOKAI Publication No. 2004-192789 has provided a semiconductor memory that prevents a write error by suppressing the fluctuation in threshold value caused by the data interference effect between adjacent cells.

In addition to a data write error, however, a read error occurs in data read because a potential difference is produced between a read target cell and adjacent cell.

### BRIEF DESCRIPTION OF THE DRAWINGS

FIG. 1 is a block diagram of a semiconductor memory device according to each embodiment;

FIG. 2 is a view showing the circuit configuration of a memory cell array of the semiconductor memory device according to each embodiment;

FIG. 3 is a view showing the arrangement of the memory cell array of the semiconductor memory device according to each embodiment;

FIG. 4 is a sectional view taken along line IV-IV in FIG. 3;

FIG. 5 is a view showing cell transistor threshold distributions related to each embodiment;

FIG. 6A is a view showing cell transistor threshold distributions for binary data according to the first embodiment;

FIG. 6B is a view showing cell transistor threshold distributions for multilevel data according to the first embodiment;

FIG. 7 is a view showing cell transistor threshold distributions according to the second embodiment;

FIG. 8 is a view showing cell transistor threshold distributions according to the third embodiment;

FIG. 9 is a view showing the arrangement of a memory cell array of a semiconductor memory device according to the fourth embodiment; and

FIG. 10 is a view for explaining a verify operation and read operation according to the fourth embodiment.

### DETAILED DESCRIPTION

In general, according to one embodiment, according to one embodiment, a semiconductor memory device comprises: a memory cell array, a controller. A memory cell array comprise sword lines, bit lines disposed perpendicularly to the word lines, and memory cells connected to the word lines and the bit lines and configured to store different states, i.e., m (a natural number of not less than 2) values or n (a natural number larger than m) values. A controller configures to control a voltage to be applied to the memory cells. When storing the n values in a memory cell selected from the memory cells, the controller performs a first method of applying a bit-line voltage higher than 0 V to a first bit line, to which the memory cell is connected, among the bit lines, and setting a second bit line adjacent to the first bit line at 0 V, in a read operation of the memory cell and in a verify operation of determining whether write to the memory cell is complete. When storing the m values in the memory cell, the controller performs a second method of applying the bit-line voltage to all the bit lines in a read operation of the memory cell, and applying the bit-line voltage to the first bit line and the second bit line or setting the first bit line and the second bit line at 0 V in a verify operation of determining whether write to the memory cell is complete, in accordance with whether the write is complete.

This embodiment will be explained below with reference to the accompanying drawing. In the drawing, the same reference numerals denote the same parts.

### [Overall Configuration Example]

First, the overall configuration of a semiconductor memory device according to this embodiment will be explained.

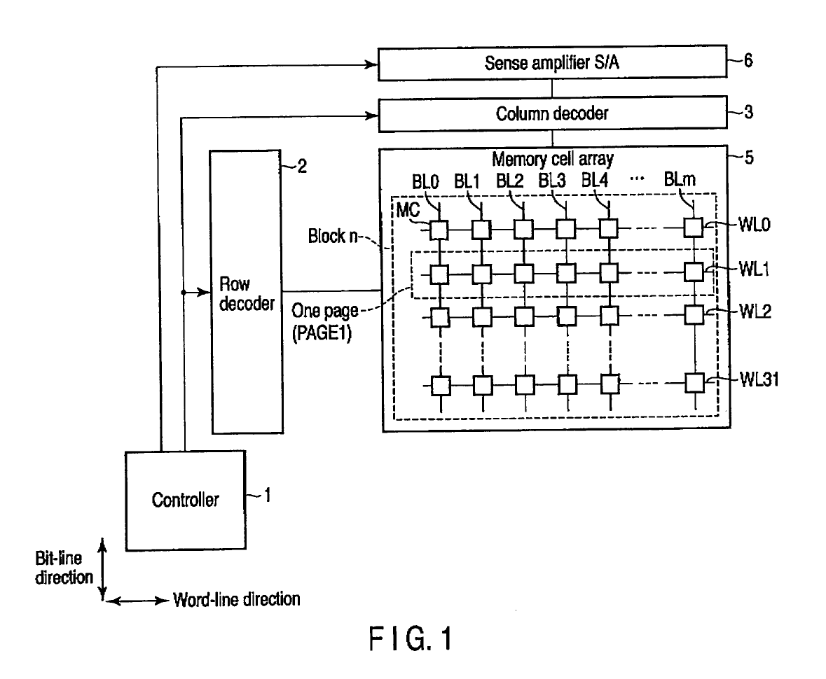

FIG. 1 is a block diagram of the semiconductor memory device according to this embodiment. As shown in FIG. 1, the semiconductor memory device includes a controller 1, row decoder 2, column decoder 3, memory cell array 5, and sense amplifier S/A 6.

The controller 1 is configured to generate voltages to be applied to the gate electrodes of memory cells and to word lines in data write, erase, and read, and control the row decoder 2, column decoder 3, and sense amplifier S/A in accordance with externally supplied addresses.

The row decoder 2 is configured to select word lines WL0 to WL31 under the control of the controller 1. Note that the number of word lines WL is 32 in this embodiment as an example, but the number of word lines WL can be changed.

The column decoder 3 is configured to select bit lines BL0 to BLm under the control of the controller 1.

The memory cell array 5 includes blocks. FIG. 1 specifically shows a block n. The block n includes word lines WL0 to WL31, bit lines BL0 to BLm, and memory cells MC arranged in a matrix.

The sense amplifier S/A 6 is configured to amplify data read out page by page from the memory cells MC to bit lines BL0 to BLm. Note that the sense amplifier S/A 6 may also be integrated with the column decoder 3.

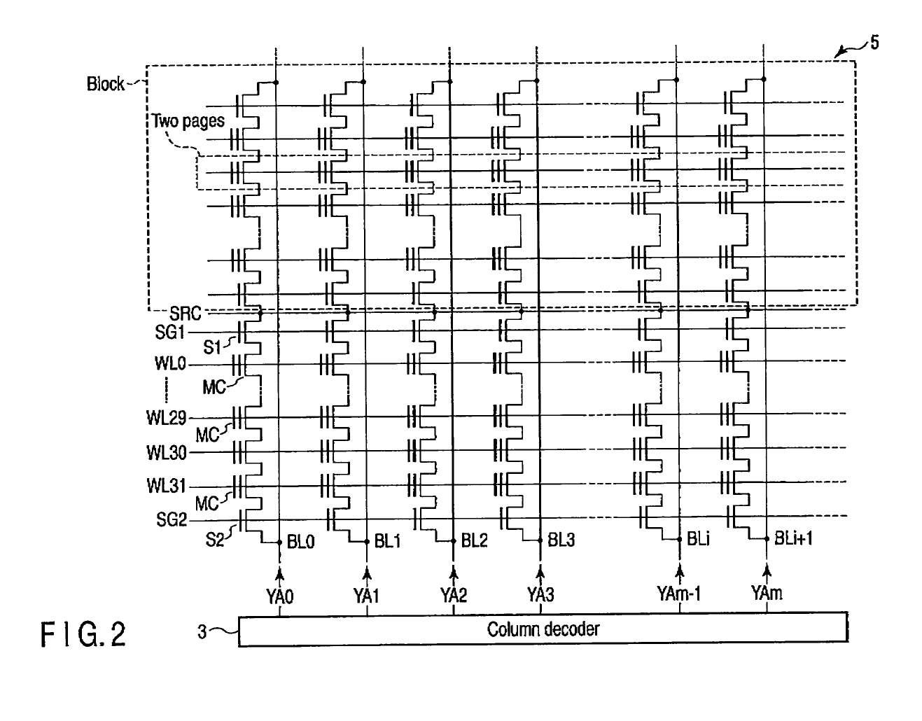

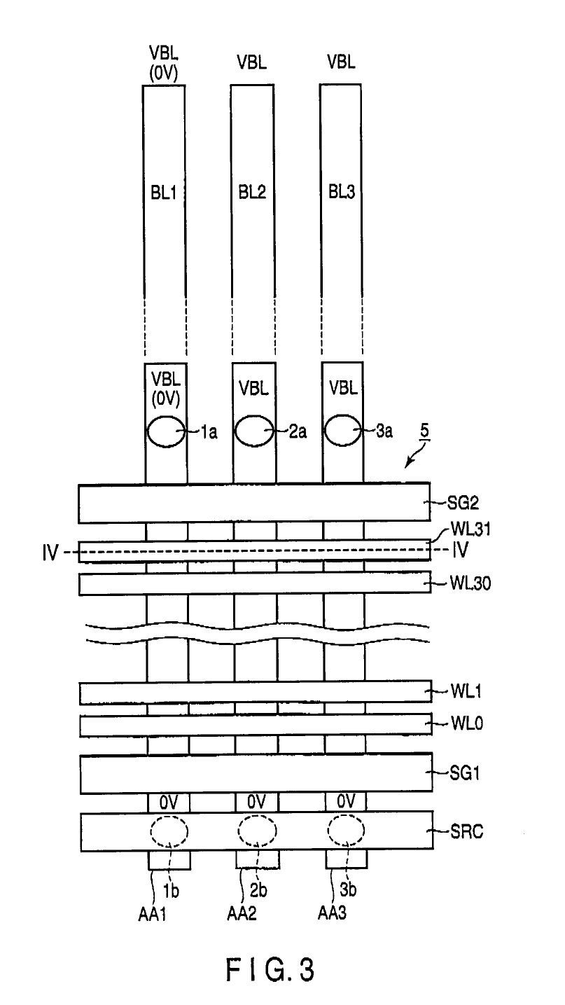

FIG. 2 shows the circuit configuration of the memory cell array 5 and column decoder 3 shown in FIG. 3. Referring to FIG. 2, the memory cell array 5 includes blocks as indicated by the broken lines. Each block includes NAND cells, and data is erased for each block.

One NAND cell includes, e.g., 32 series-connected memory cells MC, a first selection transistor S1, and a second selection transistor S2. The first selection transistor S1 is connected to a source line SRC. The second selection transistor S2 is connected to bit line BL0. The control gates of memory cells arranged on each row are connected together to a corresponding one of word lines WL0 to WL31. Also, the first selection transistors S1 are connected together to a first select gate SG1, and the second selection transistors S2 are connected together to a second select gate SG2.

In a read operation, verify operation, and programming operation, bit lines of one page are selected in accordance with address signals (YA1, YA2, . . . , YAm) designated by the column decoder 3.

### [Arrangement/Read Operation]

The arrangement of the semiconductor memory device according to this embodiment will now be explained.

FIG. 3 shows a part of the arrangement. of the memory cell array 5 shown in FIGS. 1 and 2.

As shown in FIG. 3, the memory cell array 5 includes, e.g., word lines WL0 to WL31, bit lines BL1 to BL3, first select gate SG1, second select gate SG2, and source line SRC.

Word lines WL0 to WL31 are formed by L/S (Line and Space) patterns on a semiconductor substrate (not shown). More specifically, active areas AA1 to AA3 isolated by an element isolation region (STI) are formed on a semiconductor substrate, and the word lines WL are formed perpendicularly to active areas AA1 to AA3.

The first select gate SG1 and second select gate SG2 are formed on the two sides so as to sandwich word lines WL0 to WL31. More specifically, the first select gate SG1 is formed outside word line WL0, and the second select gate SG2 is formed outside word line WL31.

The source line SRC is connected to the source side of the first select gate SG1 via contacts 1b to 3b.

Bit lines BL1 to BL3 are formed above the word lines WL in a direction perpendicular to word lines WL0 to WL31. Also, bit lines BL1 to BL3 are connected to the drain side of the second select gate SG2 via contacts 1a to 3a.

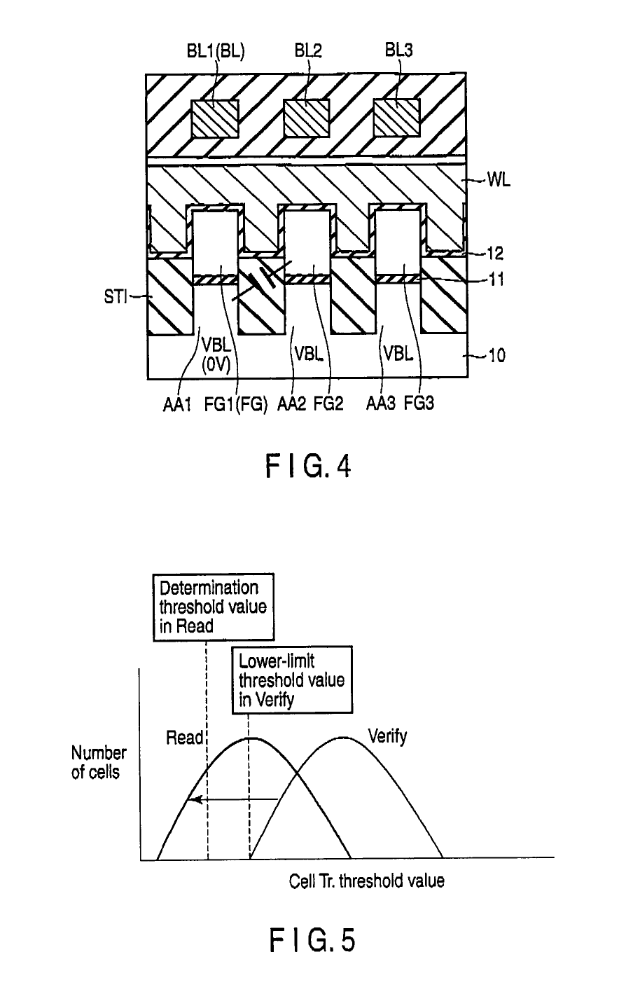

FIG. 4 is a sectional view taken along line IV-IV in FIG. 3, and showing the structure of the memory cell in this embodiment.

As shown in FIG. 4, the memory cell includes a semiconductor substrate 10, a floating gate FG, the word line WL, and the bit line BL.

Active areas AA1 to AA3 isolated by the element isolation region (STI) are formed on the semiconductor substrate 10.

Floating gates FG1 to FG3 are formed on oxide films 11 functioning as tunnel insulating films on active areas AA1 to AA3 of the semiconductor substrate 10. The floating gate FG is made of, e.g., poly-Si.

The word line WL is formed on the entire surface of an insulating film 12 so as to cover floating gates FG1 to FG3. Like the floating gate FG, the word line WL is also made of, e.g., poly-Si.

Bit lines BL1 to BL3 are formed on an insulating film on the word line WL. Bit lines BL1 to BL3 are respectively formed above floating gates FG1 to FG3. Also, bit lines BL1 to BL3 are perpendicular to the word line WL. Bit lines BL1 to BL3 are, e.g., metal interconnections.

The conventional cell data read principle will be explained below with reference to FIGS. 3 and 4.

In cell data read, a voltage VBL is applied to bit lines BL1 to BL3. The voltage VBL is transferred to the active areas via contacts 1a to 3a. The source line SRC is fixed to 0 V. In addition, voltages exceeding the threshold voltages of the first select gate SG1, the second select gate SG2, and the word lines WL except for a read target word line WL are applied to them.

More specifically, when reading out data from word line WL0, a voltage exceeding the threshold voltage of the cell transistor is applied to word lines WL1 to WL31. Then, a read voltage is applied to word line WL0 to check whether the read voltage exceeds the threshold voltage of the cell transistor (whether the cell transistor is turned on). That is, when no electrons are injected into the floating gate FG, the threshold voltage of the cell is equal to or lower than the read voltage, so the cell transistor is turned on by applying the read voltage to word line WL0. On the other hand, when electrons are injected into the floating gate FG, the threshold voltage of the cell becomes higher than the read voltage, so the cell transistor is not turned on. If the read target cell transistor is turned on, voltages exceeding the threshold voltages of the first select gate SG1, the second select gate SG2, and the word lines WL except for the read target word line WL are applied to them, so currents flow from contacts 1a to 3a to contacts 1b to 3b. However, no current flows if the cell transistor is not turned on. Whether cell data is “1” or “0” is determined based on this difference. It is, of course, also possible to store a plurality of levels (multilevel data) in a cell and read out the plurality of levels by finely setting the cell transistor threshold value.

The cell operations include a verify operation for verification after write, and a read operation of reading out stored cell data. The read operation is performed for all cells in one page at once. That is, in the read operation, the voltage VBL is applied to all bit lines. On the other hand, the verify operation is not performed for a cell for which write is complete. For example, letting A, B, and C be levels arranged in ascending order of threshold value, a verify operation of checking whether write at level A is complete is first performed. Subsequently, a verify operation of checking whether write at level B is complete is performed. No verify operation is performed for a cell for which write at level A is complete. That is, as shown in FIGS. 3 and 4, if a cell of bit line BL1 is written to level A in the verify operation of level B, the voltage VBL is not applied to bit line BL1, and bit line BL1 is set at 0 V.

As described above, the voltage VBL is applied to all the bit lines BL in the read operation, but the bit line BL of a cell adjacent to a verify target cell is sometimes set at 0 V in the verify operation. Thus, the potential of an adjacent bit line BL mainly exerts a large effect on an adjacent floating gate FG. That is, when the potential of an adjacent bit line BL is changed from VBL to 0 V in the verify operation, the threshold voltage of a target cell apparently rises due to coupling, as shown in FIG. 4.

Even when the verify operation is performed while the potential of an adjacent bit line BL is at 0 V as described above, the voltage VBL is applied to the adjacent bit line BL in the read operation. This makes the cell transistor threshold voltage in the read operation lower than that in the verify operation. Consequently, as shown in FIG. 5, the cell threshold voltage apparently shifts in the verify operation and read operation. A guard band (a voltage difference for securing a margin) is normally set between the verify voltage (lower-limit threshold value) of the verify operation and the read voltage (determination threshold value) of the read operation. However, a read error occurs if the above-mentioned threshold voltage shift amount exceeds the guard band.

Accordingly, the semiconductor memory device of this embodiment performs a read operation of avoiding the read error problem described above. The read operation of each embodiment will be explained in detail below.

### First Embodiment

The first embodiment is an example in which the potential of a cell (bit line BL) adjacent to a target cell is set at 0 V in each of the verify operation and read operation.

More specifically, each of the verify operation and read operation is performed twice. The first operation is performed for bit lines BL1 and BL3, and the second operation is performed for bit line BL2 after that. That is, the operations are alternately performed between a target cell and adjacent cells (adjacent bit lines EL). In the first operation, the voltage VBL is applied to bit lines BL1 and BL3, and bit line BL2 is set at 0 V. In the second operation after that, bit lines BL1 and BL3 are set at 0 V, and the voltage VBL is applied to the second bit line BL2. In the verify operation and read operation, therefore, equal potential differences can be set between the target cell and adjacent cells. This makes it possible to suppress the interaction between the target cell and adjacent cells.

Since the verify operation and read operation are performed as described above, the cell threshold value does not shift, but the data read time prolongs because each operation is performed twice. This point will be explained in detail below.

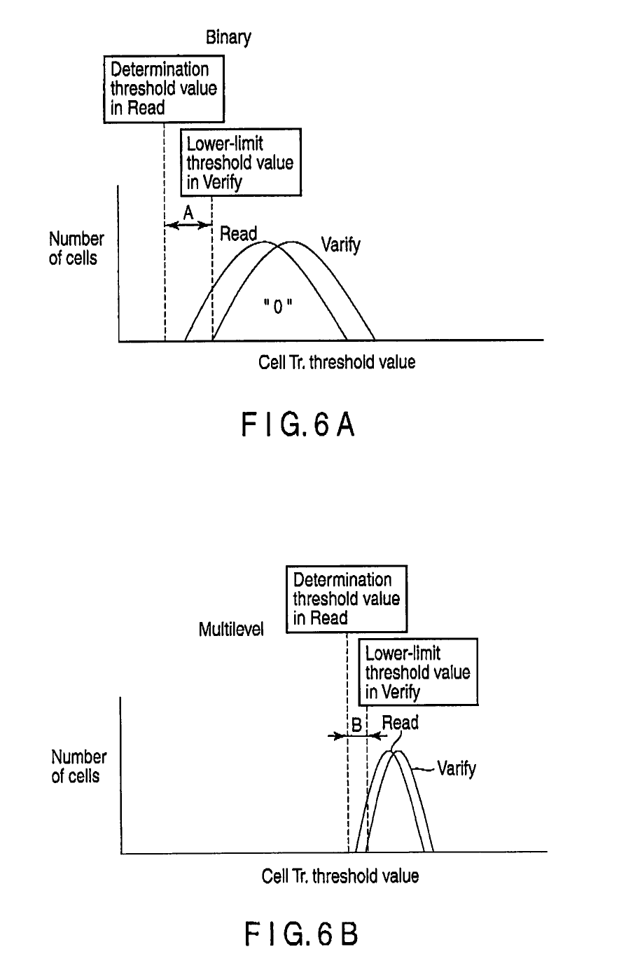

FIG. 6A shows cell transistor threshold distributions for binary data. FIG. 6B shows cell transistor threshold distributions for multilevel data.

When processing binary data, a program is not normally performed for data “1” but performed for data “0” alone. That is, two threshold levels “1” and “0” are generated for binary data. On the other hand, in a multilevel operation in which a plurality of levels are stored in one cell, a program is executed to set threshold voltages at a plurality of levels such as middle and high. Note that FIGS. 6A and 6B show the distributions of only one threshold level, and do not show other threshold levels.

When storing a plurality of levels (multilevel data) in a memory cell as shown in FIG. 6B, it is likeable to decrease variations in memory cell threshold voltage when compared to the operation of storing binary data shown in FIG. 6A. That is, it is likeable that a verify-read guard band B for multilevel data shown in FIG. 6B is smaller than a verify-read guard band A for binary data shown in FIG. 6A. More specifically, the verify-read guard band A for binary data is, e.g., about 0.5 V, and the verify-read guard band B for multilevel data is, e.g., about 0.2 V.

Normally, memory cells for multilevel data and binary data coexist in a memory cell array. When storing binary data in a memory cell, the influence on the shift of cell data as described previously is small because the guard band A is relatively large. Therefore, operation error does not occur even when using the conventional read method.

On the other hand, when storing multilevel data in a memory cell, the influence on the shift of cell data is large because the guard band B is small. Accordingly, a cell data shift caused by the voltage of an adjacent bit line BL must be controlled. That is, when performing the verify operation and read operation for multilevel data, these operations are alternately performed twice between a target cell and adjacent cells (adjacent bit lines BL) as described above.

Accordingly, a normal verify operation and undivided read operation are performed when storing binary data in a memory cell, and the verify operation and read operation are alternately performed twice each between a target cell and adjacent cells (adjacent bit lines BL) when storing multilevel data in the memory cell. The controller 1 shown in FIG. 1 controls voltages to be applied in the verify operation and read operation.

Note that it is also possible to perform the verify operation and read operation twice each when storing binary data in a memory cell, and perform a normal verify operation and undivided read operation when storing multilevel data in a memory cell. These methods are determined based on the product generations or product applications, and selectively used in accordance with the sizes of the guard bands A and B.

In the above-mentioned first embodiment, the verify operation and read operation are each performed twice by alternately applying the voltage VBL and 0 V to adjacent bit lines BL. This makes it possible to suppress the interaction caused by the potential differences between a target cell and adjacent cells, and reduce the influence of the shift of the cell threshold voltage. Accordingly, read errors can be reduced.

Also, in the first embodiment, the method of performing a normal verify operation and undivided read operation and the method of alternately performing the verify operation and read operation twice each between a target cell and adjacent cells are selectively used in accordance with the sizes of the guard bands A and B. For example, a normal verify operation and read operation are performed for binary data, and the verify operation and read operation are each performed twice for multilevel data. By thus installing the two read methods in one device, it is possible to reduce read errors and suppress the increase in read time at the same time.

### Second Embodiment

As described above, whether the voltage of an adjacent bit line BL is VBL or 0 V can be determined by checking whether a verify operation for a cell (bit line BL) adjacent to a verify target cell is complete. That is, in the read operation, whether cell data will shift can be known beforehand. Also, it is possible to predict, to some extents, both the direction and amount of shift of cell data caused by the voltage of an adjacent bit line BL.

Normally, when performing the verify operation, one verify voltage for determining whether the program is complete is used for one data. In the verify operation according to the second embodiment, however, two verify voltages are used by taking the above-mentioned points into consideration.

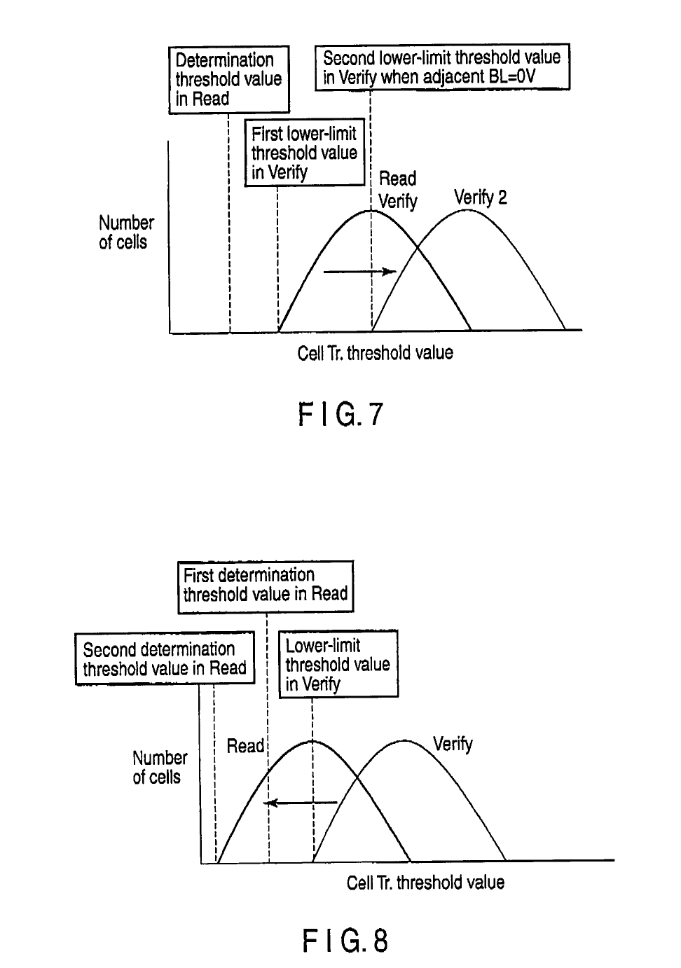

More specifically, as shown in FIG. 7, when the voltage VEIL is applied to the bit line BL of a cell adjacent to a verify target cell in the verify operation, a first verify voltage is applied to the word line WL. On the other hand, when the voltage of the bit line BL of a cell adjacent to a verify target cell is 0 V in the verify operation, a second verify voltage higher than the first verify voltage is applied to the word line WL. The program is executed by using the verify voltages as described above. The controller 1 shown in FIG. 1 controls these voltages to be applied in the verify operation. Note that in the program and verify operation for the first time, all the cell threshold voltages are at the erase voltage, so it is unnecessary to set the verify voltages as described above. In the program and verify operation from the second time, the verify voltages need only be set based on the first verify results.

In the read operation after that, the voltage VBL is applied to all the bit lines BL, and an undivided read operation is performed. In this read operation, in a cell for which the second verify voltage is used, data shifts to the low-threshold side due to the influence of the voltage of an adjacent bit line, but does not exceed the read determination threshold value.

Note that instead of the two verify voltages, three or more threshold determination levels can also be used in accordance with the voltage statuses of cells adjacent to the two sides of a verify target cell. More specifically, the above-mentioned second verify voltage is applied to the word line WL when the voltage VBL is applied to the bit line BL of a cell adjacent to one side of a verify target cell and the bit line BL of a cell adjacent to the other side is at 0 V. On the other hand, when the bit lines BL of cells adjacent to the two sides of a verify target cell are at 0 V, a third verify voltage higher than the second verify voltage is applied to the word line WL.

When performing the verify operation in the above-mentioned second embodiment, the two verify voltages are set and selectively used in accordance with whether the cell threshold voltage will shift (whether a cell (bit line BL) adjacent to a target cell is at 0 V or VBL). Accordingly, the cell threshold voltage shifts in accordance with the write state of an adjacent cell, but can be settled in the verify-read guard band. This makes it possible to reduce read errors in the read operation after that.

### Third Embodiment

As described above, the direction and amount of shift of the cell threshold voltage caused by the voltage of an adjacent bit line BL can be predicted to some extents. It is also possible to determine whether the cell threshold voltage will shift during read, based on data in an adjacent cell.

Similar to the verify voltage for determining whether programming is complete in the verify operation, one read voltage for determining “1” or “0” is normally used for one data in the read operation. In the read operation according to the third embodiment, however, the results of determination using two read voltages are held by taking account of the above-mentioned points. Which of the two determination results is to be used is determined by the threshold voltage of a cell transistor connected to the bit line BL adjacent to a read target cell. That is, in the verify operation, a determination result to be used is determined in accordance with whether the voltage applied to an adjacent bit line BL is VBL or 0 V.

For example, letting A, B, and C be levels arranged in ascending order of threshold voltage, when a verify operation of level B is performed a verify operation for a cell at level A for which write is complete is not performed, as described previously. That is, if the level of an adjacent cell is lower than that of a verify target cell, the verify operation is performed under the condition that the voltage of an adjacent bit line BL is 0 V. In this case, the cell threshold voltage shifts in the read operation. Therefore, a result obtained by performing determination by shifting the voltage of the word line to a voltage lower than the normal read voltage during the read operation is used. On the other hand, if the level of an adjacent cell is equal to or higher than that of a read target cell, the cell threshold voltage does not shift. Accordingly, a result obtained by performing determination at the normal read voltage of the read operation is used.

That is, in the read operation as shown in FIG. 8, a first read voltage and a second read voltage lower than the first read voltage are applied to the word line WL to which a read target cell belongs. That is, whether data is “1” or “0” is determined by using the first and second read voltages. A latch circuit (not shown) in, e.g., the sense amplifier S/A 6 stores a first determination result obtained by the first read voltage and a second determination result obtained by the second read voltage. The first determination result is used if the threshold voltage of a read target cell is equal to or lower than that of an adjacent cell. On the other hand, the second determination result is used if the threshold voltage of the read target cell is higher than that of the adjacent cell. In this operation, the threshold voltage of the adjacent cell is determined by using the result of the normal read voltage (first read voltage). Also, the controller 1 shown in FIG. 1 controls these voltages to be applied in the read operation.

When performing the read operation in the above-mentioned third embodiment, determination is performed using the two read voltages, and one of the two determination results is selected in accordance with whether the cell threshold value will shift (whether the threshold voltage of an adjacent cell is lower than that or equal to or higher than that of a target cell), based on data of the adjacent cell. Selectively using the two determination results as described above is equivalent to increasing the verify-read guard band. Accordingly, read errors can be reduced.

### Fourth Embodiment

### [Arrangement]

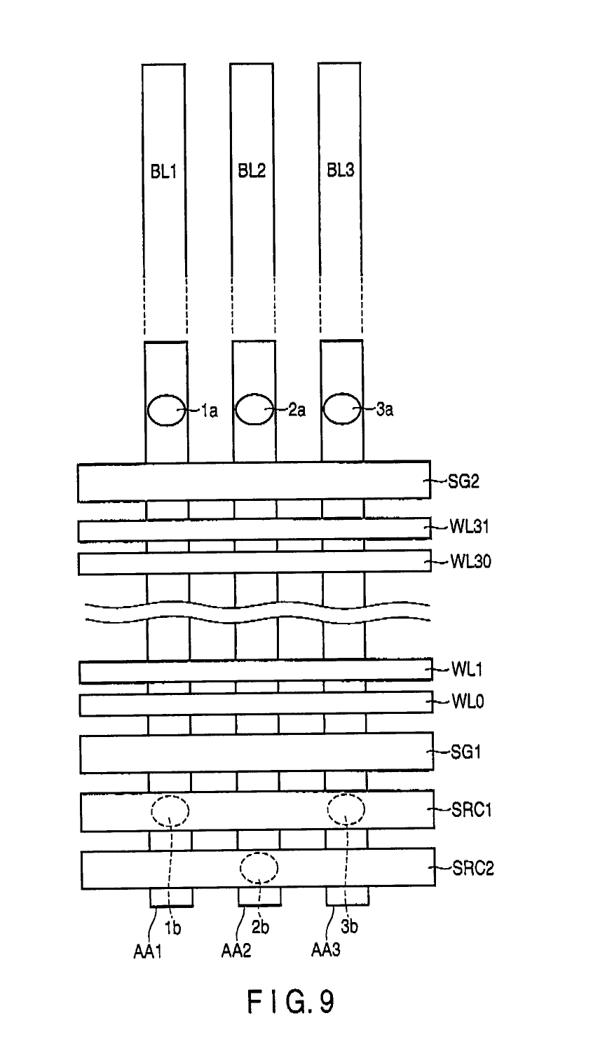

FIG. 9 shows a part of the arrangement of a memory cell array according to the fourth embodiment.

As shown in FIG. 9, the memory cell array according to this embodiment includes, e.g., word lines WL0 to WL31, bit lines BL1 to BL3, a first select gate SG1, a second select gate SG2, and source lines SRC1 and SRC2.

This embodiment differs from each of the above embodiments in that source lines SRC1 and SRC2 are formed outside the first select gate SG1. More specifically, source line SRC1 is connected to contacts 1b and 3b, and source line SRC2 is connected to a contact 2b. That is, source line SRC1 is connected to bit line BL1 via contact 1b, a channel portion of a memory cell transistor, and a contact 1a, and connected to bit line BL3 via contact 3b, a channel portion of a memory cell transistor, and a contact 3a. Source line SRC2 is connected to bit line BL2 via contact 2b, a channel portion of a memory cell transistor, and a contact 2a. Thus, source line SRC1 is connected to, e.g., odd-numbered bit lines BL, and source line SRC2 is connected to, e.g., even-numbered bit lines BL.

### [Read Operation]

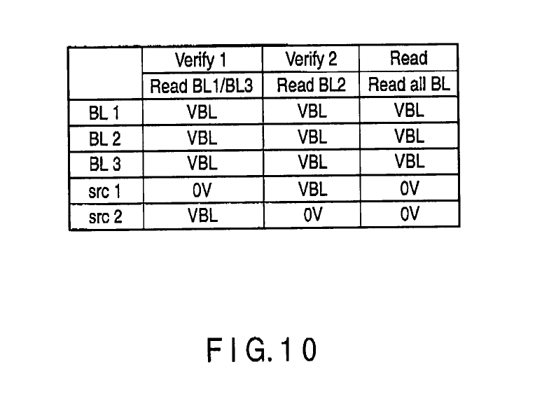

FIG. 10 shows examples of the voltage VBL to be applied in the verify operation and read operation according to this embodiment.

As shown in FIG. 10, the verify operation according to this embodiment is performed twice in the same manner as in the first embodiment. The first operation is performed for bit lines BL1 and BL3, and the second operation is performed for bit line BL2. That is, the operations are alternately performed between a verify target cell and adjacent cells (adjacent bit lines BL). The difference from the first embodiment is that the voltage VBL is always applied to all the bit lines BL.

More specifically, in the first verify operation (Verify 1), the voltage VBL is applied to bit lines BL1 to BL3. Also, source line SRC1 is set at 0 V, and the voltage VBL is applied to source line SRC2. That is, in the verify operation of bit lines BL1 and BL3, VBL is applied to contact 2a connected to bit line BL2, and contact 2b connected to source line SRC2. When write to a memory cell is not complete, therefore, currents flow through bit lines BL1 and BL3, but current does not flow through bit line BL2 regardless of the write state of the memory cell. In the second verify operation (Verify 2) after that, the voltage VBL is applied to bit lines BL1 to BL3. Also, source line SRC2 is set at 0 V, and the voltage VBL is applied to source line SRC1. That is, in the verify operation of bit line BL2, the voltage VBL is applied to contacts 1a and 3a connected to bit lines BL1 and BL3, and contacts 1b and 3b connected to source line SRC1. When write to a memory cell is not complete, therefore, current flows through bit line BL2, but no current flows through bit lines BL1 and BL3 regardless of the write state of the memory cell.

In the read operation after that, the read voltage VBL is applied to bit lines BL1 to BL3, and source lines SRC1 and SRC2 are set at 0 V. That is, the read operation is normally performed for all the bit lines BL at once.

In the above-mentioned fourth embodiment, the memory cell array includes the two source lines SRC1 and SRC2. Bit lines BL1 and BL3 are connected to source line SRC1, and bit line BL2 is connected to source line SRC2. That is, when performing the verify operation on bit lines BL1 and BL3, bit lines BL1 and BL3 and bit line BL2 are set at the same potential (e.g., VBL), and the voltages of source lines SRC1 and SRC2 are individually controlled. As a consequence, currents can be supplied to only bit lines BL1 and BL3. The current consumption can be reduced by supplying currents to only bit lines BL1 and BL3 of target cells. Furthermore, influence on floating gate FG1 due to coupling because bit lines BL1 and BL3 and bit line BL2 are at the same potential. This makes it possible to suppress cell data shift, and reduce read errors.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array comprising word lines, bit lines disposed perpendicularly to the word lines, and memory cells connected to the word lines and the bit lines and configured to store different states, i.e., m (a natural number of not less than 2) values or n (a natural number larger than m) values; and
a controller configured to control a voltage to be applied to the memory cells,
wherein when storing the n values in a memory cell selected from the memory cells, the controller performs a first method of applying a bit-line voltage higher than 0 V to a first bit line, to which the memory cell is connected, among the bit lines, and setting a second bit line adjacent to the first bit line at 0 V, in a read operation of the memory cell and in a verify operation of determining whether write to the memory cell is complete, and
when storing the m values in the memory cell, the controller performs a second method of applying the bit-line voltage to all the bit lines in a read operation of the memory cell, and applying the bit-line voltage to the first bit line and the second bit line or setting the first bit line and the second bit line at 0 V in a verify operation of determining whether write to the memory cell is complete, in accordance with whether the write is complete.

2. The device of claim 1, wherein in the first method, after applying the bit-line voltage to the first bit line and setting the second bit line at 0 V, the controller sets the first bit line at 0 V and applies the bit-line voltage to the second bit line.

3. The device of claim 1, wherein the first method and the second method are selectively used in accordance with a size of a guard band of the selected memory cell.

4. The device of claim 1, wherein the memory cell array comprises NAND cells each including a plurality of memory cells having current paths connected in series in a bit-line direction, a first selection transistor connected to one end of the plurality of memory cells, and a second selection transistor connected to the other end of the plurality of memory cells.

5. A semiconductor memory device comprising:
a memory cell array comprising word lines, bit lines formed perpendicularly to the word lines, and a first memory cell connected to a first word line among the word lines and a first bit line among the bit lines; and
a controller configured to control a voltage to be applied to the first memory cell,
wherein in a verify operation of determining whether write to the first memory cell is complete,
the controller applies a first verify voltage to the first word line, if the bit-line voltage higher than 0 V is applied to a second bit line adjacent to one side of the first bit line, and
applies a second verify voltage higher than the first verify voltage to the first word line, if the second bit line is set at 0 V.

6. The device of claim 5, wherein in a read operation of the first memory cell, the controller applies the bit-line voltage higher than 0 V to all the bit lines.

7. The device of claim 5, wherein the first verify voltage is set based on a result of a first verify operation.

8. The device of claim 5, wherein in the verify operation,
the controller applies the second verify voltage to the first word line, if the bit-line voltage is applied to the second bit line and a third bit line adjacent to the other side of the first bit-line is set at 0 V, and
applies a third verify voltage higher than the second verify voltage to the first word line, if the second bit line and the third bit line are set at 0 V.

9. The device of claim 5, wherein the memory cell array comprises NAND cells each including a plurality of memory cells having current paths connected in series in a bit-line direction, a first selection transistor connected to one end of the plurality of memory cells, and a second selection transistor connected to the other end of the plurality of memory cells.

10. A semiconductor memory device comprising:
a memory cell array having word lines, bit lines formed perpendicularly to the word lines, a first memory cell connected to a first word line among the word lines and a first bit line among the bit lines, and a second memory cell connected to the first word line and a second bit line among the bit lines adjacent to the first bit line; and
a controller configured to control a voltage to be applied to the first memory cell and the second memory cell,
wherein in a read operation of the first memory cell,
the controller applies a first read voltage and a second read voltage lower than the first read voltage to the first word line, and stores a first determination result obtained by the first read voltage and a second determination result obtained by the second read voltage,
uses the first determination result if a threshold level of the first memory cell is not more than that of the second memory cell, and
uses the second determination result if the threshold level of the first memory cell is higher than that of the second memory cell.

11. The device of claim 10, wherein in a verify operation of determining whether write to the first memory cell and the second memory cell is complete, the controller applies the bit-line voltage to the first bit line and the second bit line or sets the first bit line and the second bit line at 0 V, in accordance with whether the write is complete.

12. The device of claim 10, wherein the threshold level of the second memory cell is determined by applying the first read voltage to the first word line.

13. The device of claim 10, wherein the memory cell array comprises NAND cells each including a plurality of memory cells having current paths connected in series in a bit-line direction, a first selection transistor connected to one end of the plurality of memory cells, and a second selection transistor connected to the other end of the plurality of memory cells.
